(19) United States
(12) Patent Application Publication
(10) Pub. No.: US 2024/0341017 A1
(43) Pub. Date: Oct. 10, 2024

(54) METHOD OF OPERATING AN OPTOELECTRONIC COMPONENT AND OPTOELECTRONIC ARRANGEMENT

(71) Applicant: ams-OSRAM International GmbH, Regensburg (DE)

(72) Inventor: Viktor KRUECKL, Regensburg (DE)

(21) Appl. No.: 18/578,491

(22) PCT Filed: Jul. 12, 2022
(86) PCT No.: PCT/EP2022/069505

§ 371 Date: Jan. 11, 2024

(30) Foreign Application Priority Data
Jul. 12, 2021 (DE) 10 2021 117 963.7

(51) Int. Cl. H05B 45/14; H05B 45/58

(52) U.S. Cl. CPC H05B 45/14; H05B 45/58

(57) ABSTRACT

A method of operating an optoelectronic component for generating a target brightness includes measuring a voltage across the optoelectronic component at one or more predetermined currents and receiving a target brightness for the optoelectronic component during a time period. The method also includes determining a pulse duration to operate the optoelectronic component during the time period based on the target brightness and subdividing the pulse duration into a number of partial pulse durations. The method further includes determining partial brightnesses from the measured voltages, which are compared with the respective brightnesses, and partial currents for operating the optoelectronic component are selected on the basis of the comparison. The method additionally includes operating the optoelectronic component during each partial pulse duration with the selected partial current. The partial currents of at least two partial pulse durations are different. The partial currents can each be assigned a voltage via the optoelectronic component.

The present application claims the priority of the German application DE 10 2021 117 963.7 of Jul. 12, 2021, the disclosure of which is hereby incorporated by reference in its entirety.

The present invention relates to a method of operating an optoelectronic component to generate a target brightness. The invention also relates to a method for determining a model for predicting aging of an optoelectronic component, and to an optoelectronic component or a display device comprising a plurality of such devices.

### BACKGROUND

Nowadays, optoelectronic components, for example for light sources but also for display devices, are usually operated with a constant current. If different brightness levels are to be achieved, this can be done using pulse width modulation (PWM). An example of this can be found in U.S. Pat. No. 6,586,890B2.

Alternatively, the current can also be set variably so that the brightness is not set via the pulse length but via the current. The citations US2004/0208011A1 and US2009/0261748A1 also show two examples of this.

However, aging is a problem with such components, i.e. the brightness and possibly also the color locations change over time, so that a preset current or a preset pulse length no longer reaches the target brightness and the desired color location.

### SUMMARY OF THE INVENTION

This need is met by the objects of the independent claims. Further developments and embodiments are the subject of the dependent claims.

The inventor has recognized that the target brightness of an optoelectronic component can also be set by a combination of different currents during a predetermined total switch-on time, in addition to the length of the switch-on time during a predetermined pulse duration, since the partial brightnesses for each individual current during a partial pulse duration can be added together. If the partial brightnesses at the various currents are therefore known, a total brightness can easily be created by adding individual partial currents. The partial brightnesses are in turn a function of the voltage across the respective component. In the following, the term pulse duration is understood as the duration of the time with which the component is supplied. Another term for pulse duration is therefore the “on” time. The term pulse period refers to the time of a period, i.e. the switch-on time and the subsequent switch-off time (or vice versa). The pulse period can therefore be formed as the sum of the switch-on and switch-off times, but also as a ratio.

Accordingly, a method for operating an optoelectronic component to generate a target brightness is proposed. A target brightness for the optoelectronic component is received during a time period and a pulse duration for operating the optoelectronic component during the time period is determined therefrom.

The pulse duration is subdivided into various partial pulse durations for this purpose, so that the total switch-on time is the sum of the individual pulse durations. In this respect, the pulse duration is thus divided into a large number of partial pulse durations and the optoelectronic component is operated with a partial current during each partial pulse duration. The partial currents of at least two partial pulse durations are of different magnitudes, with partial brightnesses resulting from the voltages that can be assigned to the partial currents via the optoelectronic component, which in total over all partial brightnesses essentially result in the target brightness.

The advantage of this method is that a target brightness can be set not just by one current, but by a large number of partial currents that can be adjusted accordingly. As a result, age-related effects in particular, such as a reduction in brightness with the same current, can be compensated for. For this purpose, the process can be supplemented by the process described below.

In one aspect, a first partial current is generated with which the optoelectronic component is operated during a first partial pulse duration. This should be greater than a reference current. During a second partial pulse duration, a second partial current is provided with which the optoelectronic component is operated during a second partial pulse duration. The second partial current is smaller than the reference current. In some aspects, the partial pulse durations and the respective partial currents are selected such that the sum of the products of the partial pulse durations and the associated partial currents is the product of the total pulse duration and the reference current. Similarly, at least two of the different partial currents may be different from zero during the partial pulse durations.

In particular, the reference current can be the current with which the component would have to be operated in order to produce the target brightness for the optoelectronic component during the total pulse duration. In some embodiments, the partial pulse durations each have the same length. It is possible to interrupt the sequence of partial pulse durations briefly, i.e. to separate them by a short switch-off period. This time can be conveniently used to set the new current so that it is present without a long settling time when the device is switched on again. This improves the accuracy when setting the target brightness. The number of partial pulse durations within a period may vary and may correspond to the number of partial currents to be set. In some aspects, the number of partial pulse durations is in particular a multiple of 2.

Another aspect deals with the fact that optoelectronic components exhibit age-related degradation, so that a change in color location or a change in brightness occurs at a preset current. Although the power can be calculated from the product of the voltage drop across the component and the current flowing through the component, non-radiative recombination increases due to the ageing effects and the brightness decreases or changes with increasing age.

To compensate for this effect, the present application proposes a bundle of different measures, either individually or in combination. On the one hand, it is possible in some aspects to determine the resulting brightness by measuring the voltage across the optoelectronic component at one or more predetermined currents. The values recorded in this way can be used for calibration and incorporated into a model that generates a prediction of the further course of ageing. Alternatively, such a model can also be used to determine the total current to be set or the partial currents to be set.

If several voltage measurements can be accessed simultaneously for a model generated in this way, the predicted component brightness also matches the measured component brightness very well over a longer period of time. The model can be parameterized and stored in optoelectronic the component itself. Alternatively, it is also possible to implement the model together with some adjustable or feedable parameters as a circuit or to store it in the form of data in a memory and/or microprocessor.

Based on the predicted brightness, appropriate switch-on times t={t1, t2, . . . t_{N}} can be determined for the individual partial currents. In the same way, the necessary partial currents can also be determined for a number of fixed partial pulse durations using such a model in order to generate the desired brightness. If the component is operated with these times, the average emitted brightness can be kept almost constant over the service life of the component.

In some aspects, a large number of voltage values are recorded as a function of the partial currents through the optoelectronic component and determined separately for the individual currents. From this, a voltage vector U={U1, U2 . . . . UN} can be formed, which is suitable for predicting the emitted brightness at the different currents using a previously trained model.

In some aspects, the partial brightness is compared with the previously detected respective brightnesses and the respective partial currents for operating the optoelectronic component are selected based on the comparison. In some aspects, a table can be provided that defines the respective reference partial currents for predetermined brightnesses or voltages. The table may be based on previously measured values, but may also be generated by a model that takes into account aging effects of the optoelectronic component. For example, the table can contain interpolation points of a virtual characteristic curve, which indicates the product of voltage and current over the age of the component.

In some aspects, the partial currents for operating the optoelectronic component during each partial pulse duration can be derived from the reference partial currents from such a table. Accordingly, according to the model, in some aspects it is provided that the partial currents for operating the optoelectronic component during each partial pulse duration are derived from an age of the optoelectronic component, in particular from an operating duration of the optoelectronic component.

A further aspect relates to a method for determining a model for predicting the ageing of an optoelectronic component. A plurality of current and voltage value pairs for the optoelectronic component are recorded. These are distributed over the age or service life, so that the current-voltage value pairs characterize the optoelectronic component along the service life.

A model is generated from the various pairs of current and voltage values using machine-based learning, which maps at least one current-voltage characteristic over the age of the optoelectronic component. The model generated in this way allows a prediction of the current and/or voltage to be set at a specified target brightness. The model is then stored in a memory of an optoelectronic component or integrated into it in such a way that a prediction can be made about a pair of current-voltage values to be set and/or a current value at a specified voltage as a function of a target brightness and/or an age of the component.

This means that the model can be used in an optoelectronic component to achieve the desired brightness even over a longer service life of the optoelectronic component.

Another aspect relates to an optoelectronic arrangement. This can be part of a display device. The arrangement has an optoelectronic component which is connected in a current path that can be modulated with a PWM signal. Furthermore, a controllable current source is provided, which is connected in the current path to control a current through the optoelectronic component. A control and monitoring circuit is designed with a data input for supplying a target brightness. For this purpose, the control and monitoring circuit comprises a prediction model which takes into account the age of the optoelectronic component and which uses a target brightness to select a plurality of partial currents to supply the optoelectronic component during a pulse period.

In one aspect, the plurality of partial currents are provided during a plurality of successive partial intervals of the pulse duration to supply the optoelectronic component. A first partial current of the plurality of partial currents may be greater than a reference current and a second partial current of the plurality of partial currents may be less than a reference current. In these embodiments, the reference current represents the current with which the optoelectronic component would have to be operated during the pulse period in order to produce the target brightness.

In a further aspect, the plurality of partial currents are arranged one after the other in such a way that they represent a steadily increasing or a steadily decreasing staircase function within the pulse period. This may make it easier to program the current source and reduce interference signals when switching between the current values. In some aspects, the current pulses thus follow each other directly. In other aspects, there is a time gap between two partial currents of the plurality of partial currents within a pulse period in which the current source does not supply any current. In the case of small brightnesses to be set, it may be expedient to select at least one partial current as zero, with the at least two further partial currents of the plurality of partial currents being different.

### BRIEF DESCRIPTION OF THE DRAWING

Further aspects and embodiments according to the proposed principle will become apparent with reference to the various embodiments and examples described in detail in connection with the accompanying drawings.

FIG. 1 shows a block diagram of a section of a display device to illustrate some aspects of the proposed principle;

FIG. 2 is a representation of a current-time diagram with different current values for setting a target brightness according to the proposed principle;

FIG. 3 is an example of a procedure for generating a model with table parameters for carrying out a procedure according to the proposed principle;

FIG. 4 shows a time-pulse length diagram to illustrate the different relative pulse lengths at a desired target brightness;

FIG. 5 shows a time-brightness diagram to illustrate the proposed principle of achieving a target brightness even with older components.

### DETAILED DESCRIPTION

The following embodiments and examples show various aspects and their combinations according to the proposed principle. The embodiments and examples are not always to scale. Likewise, various elements may be shown enlarged or reduced in size in order to emphasize individual aspects. It is understood that the individual aspects and features of the embodiments and examples shown in the figures can be readily combined with each other without affecting the principle of the invention. Some aspects have a regular structure or shape. It should be noted that slight deviations from the ideal shape may occur in practice without, however, contradicting the inventive concept.

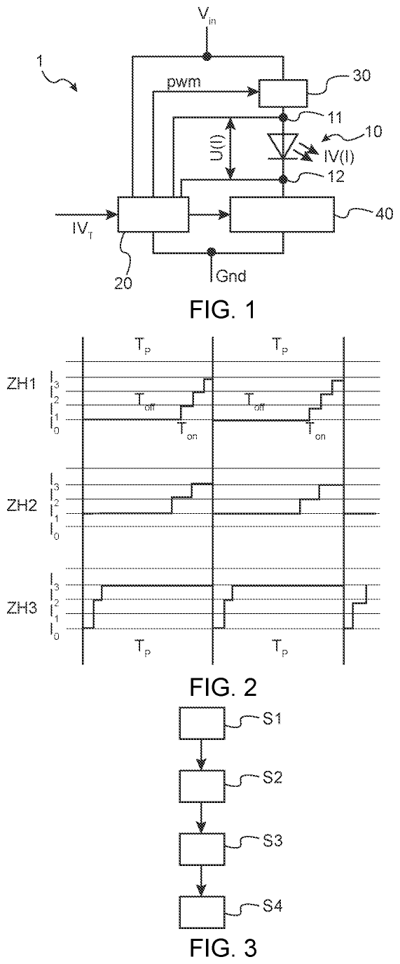

FIG. 1 shows an embodiment of an optoelectronic arrangement that can be used, for example, as part of lighting devices or display devices, projectors and the like. This embodiment can be used to illustrate both the operation of an optoelectronic component according to the proposed principle and the acquisition for creating a model by means of machine-based learning.

The arrangement 1 comprises an optoelectronic component 10, which is connected in a current path between a reference potential connection Vin and an earth potential connection GND. Two taps 11 and 12 are provided on the anode and cathode sides, via which a voltage drop can be detected as a function of a current flow through the optoelectronic component 10. The taps 11 and 12 are connected to a monitoring and control circuit 20.

The device according to the proposed principle also comprises a switching device 30, which is arranged between the reference potential connection Vin and the optoelectronic component 10. The switching device 30 is also connected to the monitoring and control circuit 40 and serves to selectively switch the optoelectronic component into the current path as a function of a pulse-modulated signal. In addition, a controllable current source 40 is arranged between the ground potential connection GND and the tap 12. This is also connected to the control circuit 20. The control and monitoring circuit 20 also comprises a data input to which, for example, a data word can be applied to set the brightness of the optoelectronic component 10 during operation. This brightness to be set is referred to below as the target brightness.

In the present embodiment example, the control and monitoring circuit 20 has the option of setting a target brightness in three ways. For example, the pulse length of the pulse-modulated signal PWM, which is supplied to the switching device 30, and a constant current, provided by the current source 40, can be set for a predetermined target brightness. In this case, the pulse length is the time duration in which the component 10 is switched into the current path and thus supplied with a current by the current source 40.

The pulse period is the sum of the so-called switch-on time Tₒₙ, in which the pulse is present and the switching device 30 is closed, and the switch-off time T_{off}, in which the switching device disconnects the current source 40 and the optoelectronic component from the supply connection Vin. The time period Tp is therefore the sum of the switch-on time Tₒₙ and the switch-off time T_{off}. In one embodiment example, the ratio of these two times can be used by the control circuit 20 to set the brightness of the component 10 at a fixed set current. This approach is well known from the prior art and allows optoelectronic components to be operated with different brightness levels, so that they can be used for lighting devices, projectors and display devices, for example.

In addition, it is also possible to control the current source 40 accordingly by means of the control and monitoring circuit with a constant modulation ratio, i.e. a constant PWM signal, and thus set the various brightness levels via the current flow. The target brightness then results from the set current of the current source 40 at a constant pulse length.

In a third example, it is also possible to regulate both the pulse length, i.e. the switch-on time, and the current through the optoelectronic component 10 simultaneously and in this way generate the desired brightness through a combination. Such a combination has the advantage that significantly greater brightness gradations can be achieved than would be possible by modulating only the duration or the current flow. In addition, brightness gradations can be represented in different ways, for example by changing the pulse duration or the current. In this respect, there are at least two possible setting variants for the control and monitoring circuit 20 for each target brightness in such a combination.

It is now also proposed to generate a specified target brightness not only by a combination of pulse length and set current, but to represent it by the sum of different partial brightnesses. Each partial brightness is defined by a specific current of a specific partial pulse duration. The total brightness of the optoelectronic component is therefore the sum of the individual partial brightnesses during a period Tp.

FIG. 2, which illustrates the proposed principle in more detail using a time-current diagram for different target brightnesses ZH1, ZH2 and ZH3, serves as an illustration. The corresponding target brightnesses are selected differently. For the target brightness ZH1, the second period Tp is divided into a switch-on time Tₒₙ and an upstream switch-off time T_{off}. In accordance with the invention, it is now intended not to apply a uniform constant current to the component during the switch-on time T₀, but also to deliver the current in various stages during the switch-on time T₀. For this purpose, the switch-on time Tₒₙ is divided into uniform sub-intervals, of which a total of three are shown for the target brightness ZH1. A predetermined constant current is now provided for each of these partial intervals and the component is supplied with it. In the present embodiment example, the current I1 is provided for the first partial interval, the larger current I2 for the second partial interval and the largest current I3 for the third partial interval. The partial intervals can also be understood as partial pulse durations.

The respective currents therefore increase over the course of the switch-on time Tₒₙ, whereby the differences in the currents are also the same in this design example. This results in the staircase function shown for the target brightness ZH1. The total brightness is essentially determined by the area under the curve during the switch-on time Tₒₙ. In this design example, assuming that the brightnesses are proportional to the current flowing through, this results in a target brightness that essentially corresponds to the switch-on time multiplied by the current I2.

In this respect, the control circuit 20 therefore has the option of achieving the desired target brightness ZH1 by dividing it into the various sub-intervals using the staircase function shown, but also by means of a constant current I2 during the switch-on time Tₒₙ. In addition, the target brightness could also be achieved in another way, for example by means of several sub-intervals connected in series, spaced by an equally large switch-off time, with the current I1 flowing during each of the switch-on times.

However, the staircase function shown for the target brightness ZH1 has the advantage that the current source 40 only has to be switched in one direction, i.e. towards increasing currents. If the settling time of the current source 40 is relatively short and does not generate any additional current or voltage peaks, the different currents can be provided directly one after the other in the various subintervals. Otherwise, it is also possible to divide the time period Tp into several sub-intervals as shown, with a short switch-off time between each sub-interval. During this time, the current source can be set to the newly defined value and then the switching device 30 can be actuated so that the component is supplied with the newly set current.

The next subfigure shows the setting for the target brightness ZH2. With this setting, the optoelectronic component is supplied with a current during the entire pulse period Tp. During a first longer time interval, current I1 is applied to the component, which is then increased to current I2 or I3 in two further sub-intervals. This results in an overall higher target brightness than curve ZH1. In addition, this embodiment example corresponds to an embodiment in which the control and monitoring circuit 20 merely controls the current source 40 accordingly in order to achieve the desired target brightness. In contrast to a constant current, however, the time period is also divided into various sub-intervals here. Different currents are now set in at least some of these sub-intervals in order to supply the optoelectronic component.

The partial figure with the target brightness ZH3 now comprises a similar design, whereby the current here rises from the initial brightness 10 after the first partial interval directly to the second current I2. Overall, this results in a relatively high current flow for the component and the target brightness ZH3 is significantly increased compared to the two previous target brightnesses ZH1 and ZH2.

The designs shown in FIG. 2 for the different target brightnesses show that the desired target brightness can be set in different ways by dividing the pulse period Tp into different sub-intervals and controlling it with different currents for the respective sub-intervals. In addition to a very precise setting of the respective desired target brightness and a particularly high resolution, the proposed principle also allows ageing effects to be at least partially compensated for. If, for example, the brightness of a component decreases at high currents due to ageing-related effects, a target brightness can still be achieved by setting additional energized partial intervals with lower currents or the partial intervals are operated with higher currents.

Especially for the compensation of ageing effects in optoelectronic components, it is necessary to know the course of ageing, i.e. the course of a characteristic curve with increasing age across the component. For this reason, it may not be sufficient to set a predetermined target brightness using different currents over the partial intervals, but it may also be necessary to be able to make a prediction about the behavior of the component over longer operating times.

For this purpose, it is proposed according to the invention to equip the control and monitoring circuit 20 with a prediction model which enables a prediction of an age-related decrease in brightness of the component. Such a model can then be used to set the desired current through the component for a target brightness to be set. To do this, it is necessary to determine the voltage drop U (I) across the component at different currents I and use the model to determine the parameters to be set. Conversely, a voltage measurement across the component at different ages of the component is also necessary to generate the model.

FIG. 1 therefore shows an embodiment in which the control and monitoring circuit 20 is basically suitable both for generating the model and for subsequent operation.

To generate a model, a test arrangement similar to FIG. 1 is used and different currents are applied to the component 10 at different target brightness settings. For each of the set currents, the voltage drop is determined via the two taps 11 and 12. In this way, a set of curves consisting of different current and voltage values is obtained for the set target brightnesses, which essentially forms a characteristic curve field of the component. Temperature-related effects can also be compensated for or taken into account when creating such a model with the various current and voltage values.

This approach is now repeated after different operating times for the component, resulting in a large number of characteristic curve fields over the operating time for the component. An ageing curve can be determined from the characteristic curve fields over the various operating times together with other parameters using a machine-based learning algorithm. This ageing curve shows the decrease in brightness of the component over the operating time. In its simplest form, the model generates a correction factor with which a target brightness must be corrected in order to compensate for the age-related decrease. For this purpose, it makes sense to also record the voltage across the component while setting the various currents to generate the target brightness as shown in FIG. 2. This results in several current-voltage values during a period Tp. The resulting points flow into the model as input parameters so that it can determine a possible age and the correction factor. As explained below, the ageing-related curves at different brightnesses are utilized, as well as the change in voltage drop over time at the same currents.

The procedure for generating such an ageing model based on a machine-based learning method is shown in FIG. 3.

In step S1 of this method, as already explained above, a large number of such characteristic curve fields are set using the desired target brightnesses and the actual brightness at the various current and voltage settings is recorded. This step is repeated in step S2 at different ages of the component so that a large number of such curves are obtained over the lifetime of the component. With increasing age, the age-related effects result in a deviation between the set target brightness and the recorded target brightness.

From these changes and the recorded data, a model can be developed using a machine-based process in step S3 with additional parameters such as the batch, the position of the optoelectronic component on the wafer, further electronic status measurements of the component and others. The model allows a prediction of the aging of the device and thus enables a correction of a set target value at a known age of the device. Conversely, as already mentioned above, the model makes it possible to determine the ageing curve on the basis of several measured voltage values and thus to determine the age and a correction factor.

This model is parameterized in step S4 and stored in the control and monitoring circuit of arrangement 1. Various options are conceivable for this. On the one hand, parameterization can be carried out using various interpolation points, which are stored in the form of a table in a memory of the control and monitoring circuit. In an operation of the arrangement according to the invention with such a parameterized model, this is used to set the necessary current and voltage values from the table at a specified target brightness. It is also possible to implement a function that maps the model so that the parameters can be set with the target brightness.

However, depending on the parameterization, the generated model is also able to determine a deviation or correction parameter depending on the service life of the component by the control and monitoring circuit, and thus to correct specified current values. Conversely, the expected voltage drops and the expected currents can be inferred from a known age and the model. In both cases, the correction parameter enables the brightness of the component to be adjusted to the desired target brightness.

By additionally using different partial intervals and the partial currents within them to create an overall brightness, a voltage vector can be formed by recording the voltage dropping across the component during the generation of the different partial brightnesses. This voltage vector can now be used to predict the emitted brightness at the different currents using the trained model.

It was found that by using several voltage measurements according to the principle presented above and taking the model into account, the component brightness predicted by the model corresponds very well with a measured component brightness.

In a practical embodiment, some components are taken from each wafer in a production batch to train the model in order to collect data in an ageing cycle. The U and IV vectors are collected and used to train a brightness model M. Since it is almost impossible to make a prediction about aging when only one voltage value is used (FIGS. 6 and 7 show such a result), the voltage values are recorded over several partial currents and used for modeling. It was found that training the ageing model with 3 to 7 voltage values and approx. 150 components of a production batch can generate a prediction of the brightness that deviates by less than 1% from the actual brightness.

The trained model can then be transferred to the model memory of the remaining components that are not yet in operation. As described above with reference to FIGS. 1 and 2, the integrated circuit or an external microcontroller then calculates the brightness at the associated currents based on several voltage measurements and generates an optimized pulse structure from this. For this purpose, the partial pulse durations t={t₀; t₁; : : : ; t_{N}} must be selected so that the target brightness IV_{T}=Σᵢtᵢ/Tp IVᵢ is set based on the predicted brightness IVᵢ and the desired period duration Tp. For low brightness levels, a time window to without energization with IV₀=0 is necessary. A possible solution to the problem is based on dividing the currents into two groups, darker or brighter than the target brightness IV_{T}

$$\\ IV <= \{ {IV}_{i} \vert {IV}_{i} < {IV}_{T} \} and {IV}_{\geq } = \{ {IV}_{i} \vert {IV}_{i} \geq {IV}_{T} \} with$$

$$\\ {t}_{<} = \frac{T}{dim ( {IV}_{<} )} * \frac{avg ( {IV}_{\geq } ) - {IV}_{T}}{avg ( {IV}_{\geq } ) - avg ( {IV}_{<} )} and {t}_{\geq } = \frac{T - {t}_{<} * dim ( {IV}_{<} )}{dim ( {IV}_{\geq } )}$$

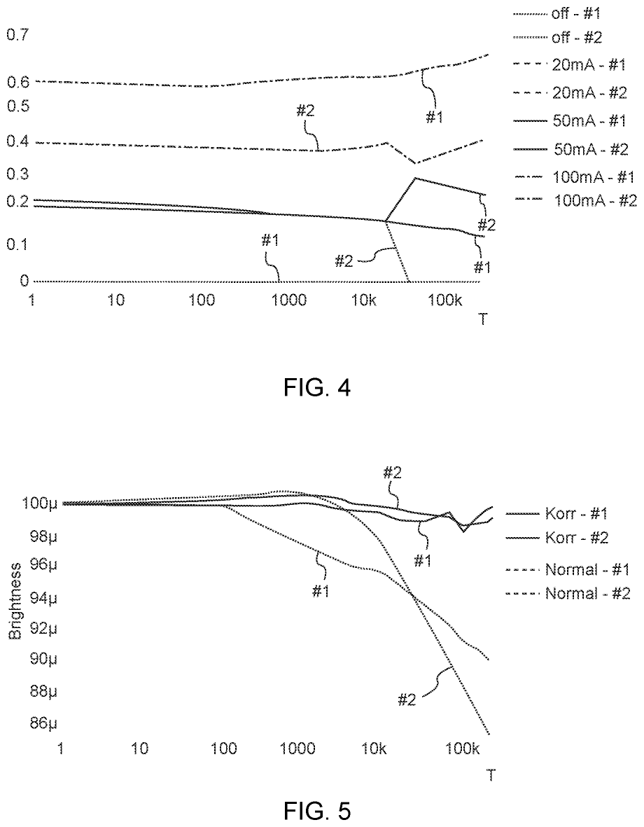

FIG. 4 shows an example of the result of such a model. The relative pulse duration for setting the various currents over the lifetime of a total of two components is shown for a specific target brightness. The components are labeled #1 and #2 respectively. A total of four partial pulses are used to set the desired target brightness, a first pulse during which the component is essentially switched off, a second pulse with a current flow of 20 mA, a third pulse with a current flow of 50 mA and a fourth current pulse with a current of 100 mA. For components #1 and #2, this results in the relative pulse duration for the respective currents shown in the following table at time T=10:

| Currents | Component #1 | Component #2 |
|---|---|---|
| Off | 0 | 0.2 |
| 20 mA | 0.21 | 0.2 |
| 50 mA | 0.21 | 0.2 |
| 100 mA | 0.57 | 0.4 |

It can be seen that the two components are quite different in the range of the highest current at 100 mA and for no current over the entire service life. However, it is also noticeable that additional deviations occur between the components at higher lifetimes of around T=10k to T=100k. In addition, the various current settings change, so that a clear deviation from the individual currents at the desired target brightness can be seen, especially at older lifetimes.

For example, for the desired target brightness in the range of T=50k for component #2, the relative pulse duration for the switched-off state, i.e. I=0, decreases from about 0.2 to zero. This immediately results in the ageing-related degradation effect for component #2 reducing the brightness, so that the desired brightness can now only be achieved by the other current curves, in particular the curve for 50 mA. In other words, the partial interval for the current at 50 mA is extended and thus the relative pulse duration for this current is increased with a longer service life in order to achieve the desired target brightness.

This additional correction using the model, in which the respective currents can be evaluated by recording the voltage values and using the model, makes it possible to compensate for the age-related effect of a decrease in brightness.

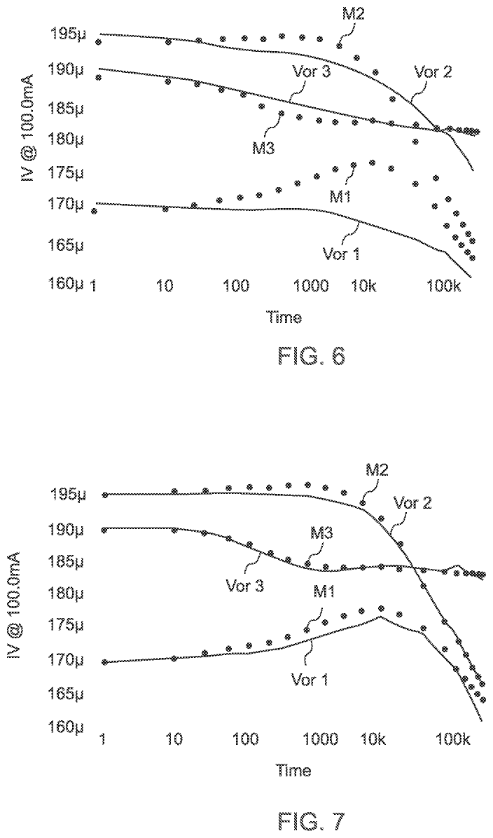

The result is shown in FIG. 5, which represents the desired brightness over time for the corrected curves and the uncorrected curves as shown in FIG. 4. The corrected curves are shown as continuous lines, the uncorrected curves as dashed lines. A decrease in brightness can be clearly seen even after a short service life in the range of T=1000 for both components in the uncorrected state. In contrast, the target brightness of 100u can be achieved with the corrected curves even over a long service life of the component up to T>100k with only small percentage deviations. By predicting the ageing of the component using the principle proposed here and the model generated in this way, the target brightnesses can still be achieved by providing different currents at partial intervals, even at higher lifetimes. The different currents allow the ageing-related degradation effect to be compensated for without having to change the pulse width, for example.

Another aspect concerns the predictive accuracy of the model generated using the proposed method. As already mentioned, it is necessary to record current and voltage values for a large number of components in order to train the model. The necessary current and voltage parameters can then be taken from the model for a desired target brightness.

For this purpose, it is useful to record the voltage values at the set partial currents during operation of the component and to use these as input parameters for the model. FIG. 6 shows the prediction accuracy of a model at different brightness values if only the voltage value at the set partial current of 100 mA is measured and this is used as an input parameter. The solid lines show the respective prediction curves from the model with a single voltage value as input parameter. The prediction Vor1 essentially consists of the initial brightness 170p at t=0, as well as the calculated brightness changes for t>0. The curves Vor2 and Vor3 show the respective brightnesses of two further validation components with an initial brightness of 190u and 195u respectively.

In this example, the deviation between the prediction and the measured values marked with dots over the component service life can be clearly seen. In particular, the prediction Vor1 for the validation component #1 deviates significantly from the measured curves for longer operating times.

With the proposed principle for creating a model and operating the component, however, the entire pulse duration can be divided into different partial pulse durations, and each partial pulse duration can be operated with different currents and voltages and thus brightnesses, so that the total brightness can be represented as the sum of the individual partial brightnesses. A voltage value can now also be determined for each of these partial currents and used to generate the model. When using several measured voltage values, the prediction accuracy of the model improves considerably, so that the overall deviation is only a few percent.

FIG. 7 shows an example with the same target brightness as in the previous example. However, the prediction of the component brightness is now based on several voltage measurements at partial currents of 20 mA, 50 mA and 100 mA. The prediction of the model generated in this way now matches the measured values surprisingly well, especially in the areas of greater change, particularly with older components. With such a pulse modulation with different partial currents, which are each applied in partial pulse durations for the supply of the current through the optoelectronic component, the deviation is only about +1% over the service life of the component. The proposed method, the model calculated with the method and operation of the component according to the proposed principle can guarantee the target brightness even in the case of ageing-related effects.

### REFERENCE LIST

1 device
10 optoelectronic component
11, 12 taps
20 Control and monitoring circuit
30 switching device
40 adjustable power source
ZH1 target brightness curve
ZH2, TH3 target brightness curves
Tp time period
Tₒₙ switch-on time
T_{off} switch-off time

1. A method of operating an optoelectronic component for generating a target brightness, the method comprising:
measuring of a voltage across the optoelectronic component at one or more predetermined currents;
receiving a target brightness for the optoelectronic component during a time period;
determining a pulse duration to operate the optoelectronic component during the time period based on the target brightness;
subdividing the pulse duration into a number of partial pulse durations;
determining partial brightnesses from the measured voltages, which are compared with the respective brightnesses and the respective partial currents for operating the optoelectronic component are selected on the basis of the comparison; and
operating the optoelectronic component during each partial pulse duration with the selected partial current, wherein the partial currents of at least two partial pulse durations are different;
and the partial currents can each be assigned a voltage via the optoelectronic component, from which a partial brightness results during the partial pulse duration, so that the partial brightnesses during all partial pulse durations essentially result in the target brightness.

2. The method according to claim 1, wherein a first partial current with which the optoelectronic component is operated during a first partial pulse duration is greater than a reference current, and a second partial current with which the optoelectronic component is operated during a second partial pulse duration is less than the reference current.

3. The method according to claim 2, wherein the reference current represents the current with which the optoelectronic component would have to be operated during the pulse duration in order to give the target brightness.

4. The method according to claim 1, wherein the partial pulse durations each have the same length and their number is in particular a multiple of 2.

5. The method according to claim 1, wherein the measured voltage values are processed in a model to predict a total brightness derived from the measured voltage values.

6. The method according to claim 5, further comprising providing a model, wherein one or more partial currents to be adjusted are set from the model and the received target brightness.

7. The method according to claim 1, further comprising providing a table defining respective reference partial currents for predetermined brightnesses or voltages.

8. The method according to claim 7, wherein the partial currents for operating the optoelectronic component during each partial pulse duration are derived from the reference partial currents.

9. The method according to claim 1, wherein the partial currents for operating the optoelectronic component during each partial pulse duration are derived from an age of the optoelectronic component, in particular from an operating time of the optoelectronic component.

10. The method according to claim 1, wherein at least two of the different partial currents are different from zero during the partial pulse durations.

11. A method for determining a model for predicting aging of an optoelectronic component, the method comprising;
detecting a plurality of pairs of current and voltage values for the optoelectronic component at different ages of the optoelectronic component;
generating a model by means of machine-based learning which depicts at least one current-voltage characteristic curve over the age of the optoelectronic component;
storing the model in a memory of an optoelectronic component in such a way that the model makes a prediction about a current-voltage value pair to be set and/or a current value at a given voltage as a function of a target brightness and/or an age of the component.

12. An optoelectronic arrangement comprising:
an optoelectronic component that can modulate a PWM signal and is connected in a current path;
a controllable current source connected in the current path to control a current through the optoelectronic component;
a control and monitoring circuit with a data input for supplying a target brightness;
wherein the control and monitoring circuit is designed with a prediction model which takes into account an age of the optoelectronic component and which selects a plurality of partial currents for supplying the optoelectronic component during a pulse period on the basis of a target brightness.

13. The optoelectronic arrangement according to claim 12, wherein the plurality of partial currents are provided during a plurality of successive partial intervals of the pulse duration to power the optoelectronic component.

14. The optoelectronic arrangement according to claim 12, wherein a first partial current of the plurality of partial currents is greater than a reference current and second partial current of the plurality of partial currents is less than a reference current.

15. The optoelectronic arrangement according to claim 14, wherein the reference current represents the current with which the optoelectronic component would have to be operated during the pulse period in order to give the target brightness.

16. The optoelectronic arrangement according to claim 12, wherein the plurality of partial currents are arranged one behind the other in such a way that they represent a continuously rising or a continuously falling staircase function within the pulse period.

17. The optoelectronic arrangement according to claim 12, wherein there is a time gap between two partial currents of the plurality of partial currents within a pulse period in which the current source supplies no current.

18. The optoelectronic arrangement according to claim 12, wherein at least two of the plurality of partial currents are different, and at least one further partial current is zero.
